(19) United States
(12) Patent Application Publication
(10) Pub. No.: US 2026/0051848 A1
(43) Pub. Date: Feb. 19, 2026

(54) Tunable Magnetic Coupling for Complementary Oscillator Circuitry

(71) Applicant: Apple Inc., Cupertino, CA (US)

(72) Inventor: Omar E. Elaasar, San Diego, CA (US)

(21) Appl. No.: 19/183,523

(22) Filed: Apr. 18, 2025

Related U.S. Application Data
(60) Provisional application No. 63/684,777, filed on Aug. 19, 2024.

(51) Int. Cl. H03B 5/12; H04B 1/40

(52) U.S. Cl. CPC H03B 5/1212; H04B 1/40

(57) ABSTRACT

Oscillator circuitry is provided that includes a pair of n-type transistors coupled to a first tail node, a pair of p-type transistors coupled to a second tail node, a first tail coil coupled to the first tail node, and a tunable magnetic coupling circuit magnetically coupled to the first tail coil. The oscillator can further include a load inductor, a load capacitor, a second tail coil coupled to the second tail node and magnetically coupled to the tunable magnetic coupling circuit, and a tunable capacitor having a first terminal coupled to the first tail node and having a second terminal coupled to the second tail node. The tunable magnetic coupling circuit can include a first coupling coil magnetically coupled to the first tail coil, a second coupling coil magnetically coupled to the second tail coil, and a programmable resistor coupled to the first and second coupling coils in a loop.

This application claims the benefit of U.S. Provisional Ser. No. 63/684,777, filed Aug. 19, 2024, which is hereby incorporated by reference herein in its entirety.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless communications circuitry in the wireless communications circuitry uses the antennas to receive and transmit radio-frequency signals.

The wireless communications circuitry can include a transceiver having one or more mixers. A mixer in the transmit path can be used to modulate signals from a baseband frequency to a radio frequency, whereas a mixer in the receive path can be used to demodulate signals from the radio-frequency to the baseband frequency. Mixers receive clock signals generated from local oscillator circuitry. It can be challenging to design satisfactory local oscillator circuitry for an electronic device.

### SUMMARY

An aspect of the disclosure provides oscillator circuitry that includes a pair of n-type transistors coupled to a first tail node, a pair of p-type transistors coupled to a second tail node, output terminals coupled between the pair of n-type transistors and the pair of p-type transistors, the output terminals configured to provide an oscillating signal, a first tail coil coupled to the first tail node, and a tunable magnetic coupling circuit magnetically coupled to the first tail coil. The oscillator circuitry can further include a second tail coil coupled to the second tail node and magnetically coupled to the tunable magnetic coupling circuit and can further include a tunable capacitor having a first terminal coupled to the first tail node and having a second terminal coupled to the second tail node. The tunable magnetic coupling circuit can include a first tuning coil magnetically coupled to the first tail coil, a second tuning coil magnetically coupled to the second tail coil, and a programmable resistor coupled to the first and second tuning coils in a loop. The tunable capacitor can be configured to provide a first capacitance value for optimizing phase noise rejection for the oscillator circuitry when the programmable resistor has a first resistance value and can be configured to provide a second capacitance value, different than the first capacitance value, for optimizing phase noise rejection for the oscillator circuitry when the programmable resistor has a second resistance value different than the first resistance value.

An aspect of the disclosure provides circuitry that includes a pair of n-type transistors coupled to a first tail node, a pair of p-type transistors coupled to a second tail node, a first tail coil coupled to the first tail node, a second tail coil coupled to the second tail node, and a tunable magnetic coupling circuit operable in a first coupling mode for providing a first amount of magnetic coupling between the first and second tail coils and further operable in a second coupling mode for providing a second amount of magnetic coupling, different than the first amount of magnetic coupling, between the first and second tail coils. The circuitry can further include an adjustable capacitor having a first node coupled to the first tail node and having a second node coupled to the second tail node. The tunable magnetic coupling circuit can include a first tuning coil magnetically coupled to the first tail coil, a second tuning coil magnetically coupled to the second tail coil, and a programmable resistor having a first terminal coupled to the first tuning coil and having a second terminal coupled to the second tuning coil.

The programmable resistor can be configured to provide a first resistance value when the tunable magnetic coupling circuit is operated in the first coupling mode and can be configured to provide a second resistance value, different than the first resistance value, when the tunable magnetic coupling circuit is operated in the second coupling mode. When the tunable magnetic coupling circuit is configured in the first coupling mode, the first tail coil is magnetically decoupled from the second tail coil. When the tunable magnetic coupling circuit is configured in the second coupling mode, the first tail coil is magnetically coupled to the second tail coil. When the tunable magnetic coupling circuit is configured in the first coupling mode, the circuitry can be configured to operate at a first resonant frequency. When the tunable magnetic coupling circuit is configured in the second coupling mode, the circuitry can be configured to operate at a second resonant frequency higher than the first resonant frequency.

An aspect of the disclosure provides circuitry that includes a pair of cross-coupled n-type transistors coupled to a first tail node, a pair of cross-coupled p-type transistors coupled to a second tail node, a load inductor coupled between the pair of cross-coupled n-type transistors and the pair of cross-coupled p-type transistors, a load capacitor coupled in parallel with the load inductor, and a phase noise filter coupled between the first and second tail nodes and having a programmable resistor. The programmable resistor can be configured to provide: a first resistance in a first mode, where the phase noise filter exhibits a first inductance in the first mode; and a second resistance, less than the first resistance, in a second mode, where the phase noise filter exhibits a second inductance, less than the first inductance, in the second mode. The phase noise filter can further include: a first tuning coil and a second tuning coil coupled to the programmable resistor in a loop, a first tail coil coupled to the first tail node and magnetically coupled to the first tuning coil, and a second tail coil coupled to the second tail node and magnetically coupled to the second tuning coil.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having oscillator circuitry in accordance with some embodiments.

FIG. 3 is a diagram of illustrative complementary oscillator circuitry having a transformer based phase noise filter in accordance with some embodiments.

FIG. 4 is a circuit diagram showing an illustrative implementation of the complementary oscillator circuitry of FIG. 3 in accordance with some embodiments.

FIG. 5 is a circuit diagram of an illustrative programmable resistor in accordance with some embodiments.

FIG. 6 is a circuit diagram of an illustrative programmable resistor in accordance with some embodiments.

FIG. 7 is circuit diagram of an illustrative phase noise filter configured to operate in a first mode in accordance with some embodiments.

FIG. 8 is circuit diagram of an illustrative phase noise filter configured to operate in a second mode in accordance with some embodiments.

FIG. 9 is a plot of effective inductance of the phase noise filter as a function of frequency across different programmable resistor values in accordance with some embodiments.

FIG. 10 is a plot of phase noise as a function of differential capacitance across different programmable resistor values in accordance with some embodiments.

### DETAILED DESCRIPTION

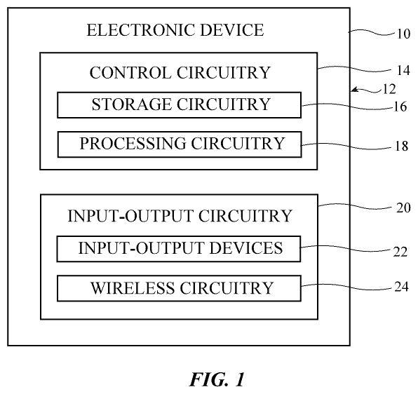

An electronic device such as electronic device 10 of FIG. 1 may be provided with wireless circuitry. The wireless circuitry can include one or more mixers and oscillator circuitry configured to generate oscillating signals or clock signals that are supplied to the one or more mixers. The oscillator circuitry can be a voltage controlled oscillator (VCO) having one or more inductors and a tunable capacitor. Such type of voltage controlled oscillator is sometimes referred to as an “LC” (inductor-capacitor) VCO. An LC VCO can include both n-type transistors and p-type transistors; such type of LC VCO is sometimes referred to as a “complementary” LC VCO. The n-type transistors can be coupled to a first power supply line via a first tail inductor, whereas the p-type transistors can be coupled to a second power supply line via a second tail inductor.

In accordance with an embodiment, a complementary LC VCO can be provided with a transformer based phase noise (tail) filter or resonator that is coupled between the n-type transistors and p-type transistors. The transformer based phase noise resonator can include a tunable differential capacitor and a tunable magnetic coupling circuit that is inductively coupled to the first and second tail inductors. The tunable magnetic coupling can include a first inductor magnetically coupled to the first tail inductor, a second inductor magnetically coupled to the second tail inductor, and a programmable resistor coupled between the first and second inductors in a loop. The programmable resistor can be adjusted to provide a wide range of resistance values to control an amount of magnetic coupling between the first and second tail inductors depending on a resonance frequency of the phase noise filter. A complementary LC VCO having a phase noise tail filter configured and operated in this way can be technically advantageous and beneficial to provide an extended filter tuning range without sacrificing the quality (Q) factor of the filter.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or THF bands), etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

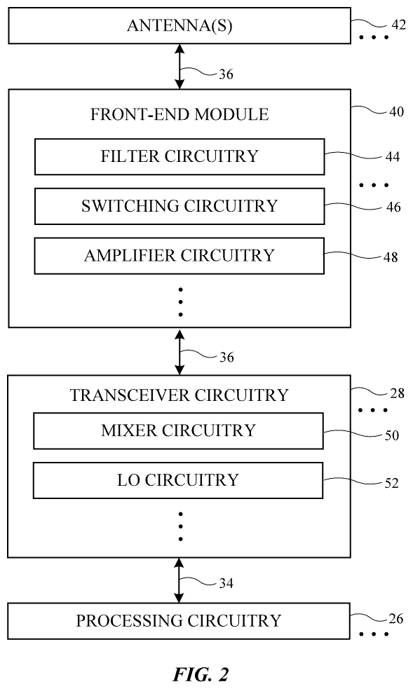

FIG. 2 is a diagram showing illustrative components within wireless circuitry 24. Wireless circuitry 24 can include, as part of oscillator circuitry 52, a balun phase noise filter with improved phase noise suppression capabilities. As shown in FIG. 2, wireless circuitry 24 may include one or more processors such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may be baseband processing circuitry, one or more application processor, one or more digital signal processor, one or more microcontroller, one or more microprocessor, one or more central processing unit (CPU), one or more programmable device, a combination of these circuits, and/or other types of processors within circuitry 18. Processing circuitry 26 may be configured to generate digital (transmit or baseband) signals. Processing circuitry 26 may be coupled to transceiver 28 over path 34 (sometimes referred to as a baseband path). Transceiver 28 may be coupled to antenna 42 via radio-frequency transmission line path 36. Radio-frequency front-end module 40 may be interposed on radio-frequency transmission line path 36 between transceiver 28 and antenna 42.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

In the example of FIG. 2, wireless circuitry 24 is illustrated as including a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective paths 34. Each transceiver 28 may include a transmitter circuit configured to output uplink signals to antenna 42, may include a receiver circuit configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module interposed thereon.

Front-end module (FEM) 40 may include radio-frequency front-end circuitry that operates on the radio-frequency signals conveyed (transmitted and/or received) over radio-frequency transmission line path 36. Front-end module may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers and one or more low-noise amplifiers), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip.

Filter circuitry 44, switching circuitry 46, amplifier circuitry 48, and other circuitry may be interposed within radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc.

Transmission lines in device 10 such as transmission lines in radio-frequency transmission line path 36 may be integrated into rigid and/or flexible printed circuit boards. In one suitable arrangement, radio-frequency transmission line paths such as radio-frequency transmission line path 36 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

In performing wireless transmission, processor 26 may provide digital signals to transceiver 28 over path 34. Transceiver 28 may further include circuitry for converting the baseband signals received from processor 26 into corresponding intermediate frequency or radio-frequency signals. For example, transceiver circuitry 28 may include mixer circuitry 50 for up-converting (or modulating) the baseband signals to intermediate frequencies or radio frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may include a transmitter component to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from external wireless equipment. The received radio-frequency signals may be conveyed to transceiver 28 via radio-frequency transmission line path 36 and front-end module 40. Transceiver 28 may include circuitry for converting the received radio-frequency signals into corresponding intermediate frequency or baseband signals. For example, transceiver 28 may use mixer circuitry 50 for downconverting (or demodulating) the received radio-frequency signals to baseband frequencies prior to conveying the received signals to processor 26 over path 34.

Mixer circuitry 50 can include local oscillator circuitry such as local oscillator (LO) circuitry 52. Local oscillator circuitry 52 can generate oscillator or oscillating signals that mixer circuitry 50 uses to modulate transmitting signals from baseband frequencies to radio frequencies and/or to demodulate the received signals from radio frequencies to baseband or intermediate frequencies. Local oscillator circuitry 52 can generally include phase-locked loop (PLL) circuitry configured to generate the oscillating signals being fed to inputs of mixer circuitry 50.

In practice, phase noise in this local oscillator path can have a direct impact on the signal-to-noise and distortion ratio (SNDR), which, if care is not taken, can degrade the error vector magnitude (EVM) of wireless circuitry 24. As state-of-the-art modulation schemes impose more stringent EVM requirements, the phase noise in the oscillator path can become a dominant factor in the overall link budget. The PLL circuitry can include an oscillator such as a voltage controlled oscillator (VCO). It can be challenging to design a VCO for wireless circuitry 24.

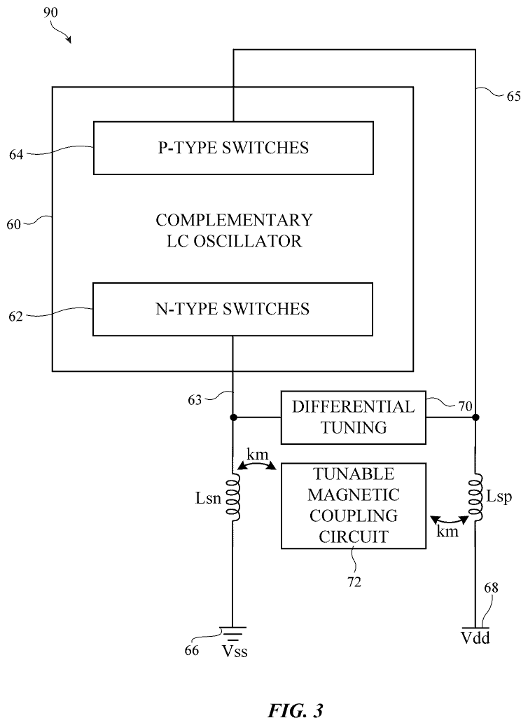

FIG. 3 is a diagram of illustrative oscillator circuitry such as oscillator circuitry 90 having a transformer based phase noise filter in accordance with some embodiments. Oscillator circuitry 90 can represent an oscillator such as a voltage controlled oscillator (VCO) that may be part of a phase-locked loop (PLL) for generating oscillating signals in LO circuitry 52. As shown in FIG. 3, oscillator circuitry 90 may include an oscillator subcircuit 60 that includes inductor (L) and capacitor (C) components and is thus sometimes referred to herein as an “LC” oscillator subcircuit or portion. Oscillator subcircuit 60 may further include n-type switches such as n-type transistors 62 and p-type switches such as p-type transistors 64. Oscillator subcircuit 60 that includes both n-type transistors and p-type transistors is sometimes referred to and defined herein as a “complementary”oscillator subcircuit.

In the example of FIG. 3, the n-type transistors 62 can be coupled to a first tail coil (inductor) such as first tail coil Lsn via connection path 63. The first tail coil Lsn can have a first terminal coupled to the n-type transistors 62 and a second terminal coupled to a ground power supply line 66 (e.g., a ground power supply terminal on which ground voltage Vss is provided). Tail coil Lsn having one side coupled to a power supply line can be referred to as a “single-ended” coil or inductor. On the other end, the p-type transistors 64 can be coupled to another tail coil (inductor) such as second tail coil Lsp via connection path 65. The second tail coil Lsp can have a first terminal coupled to the p-type transistors 64 and a second terminal coupled to a positive power supply line 68 (e.g., a positive power supply terminal on which positive power supply voltage Vdd is provided). Tail coil Lsp having one side coupled to a power supply line can also be referred to as a “single-ended”coil or inductor.

A differential tuning component such as differential tuning component 70 can be coupled between tail coil Lsn and tail coil Lsp. As an example, the differential tuning component 70 can be an adjustable capacitor. If desired, tuning component can employ other types of tunable electrical components. Device configurations in which differential tuning component 70 is an adjustable capacitor are sometimes described herein as an example. As examples, differential adjustable capacitor 70 can be an adjustable capacitor implemented as a bank of switchable capacitors (e.g., an array of capacitors each of which is selectively activated by a respective switch), a variable capacitor sometimes referred to as a varactor, a varicap diode, a metal-oxide-semiconductor capacitor (MOSCAP), and/or other components configured to provide a variable capacitance. Component 70 is thus sometimes referred to herein as a differential tuning capacitor.

Differential tuning capacitor 70, along with tail coils Lsn and Lsp, can form part of a phase noise filter that is configured to suppress close-in phase (flicker) noise for oscillator circuitry 90. Such phase noise filter that can include the tail coils Lsn and Lsp can thus sometimes be referred to as a phase noise “tail” filter. The quality (Q) factor of the phase noise tail filter can impact the amount of phase noise suppression. In particular, the quality factor and tuning range of the phase noise tail filter may be dependent on the quality factor and parasitic capacitance of differential tuning capacitor 70. On one hand, implementing tuning capacitor 70 using large switches that provide small on-state resistance can provide a high quality factor. On the other hand, implementing tuning capacitors 70 using small switches having small parasitic capacitance can provide a wider tuning range. The size of the switches within tuning capacitor 70 can thus sometimes impose a tradeoff between the tuning range and the quality factor of the phase noise tail filter.

In accordance with an embodiment, the phase noise tail filter can further include a tunable magnetic coupling circuit such as tunable magnetic coupling circuit 72 selectively coupled between the tail coils Lsn and Lsp. Thus, components Lsn, Lsp, 70, and 72 can all be considered to be part of the phase noise tail filter. Tunable magnetic coupling circuit 72 can be magnetically coupled to tail coil Lsn by a first magnetic coupling factor (coefficient) km and can be magnetically coupled to tail coil Lsp by a second magnetic coupling factor (coefficient) km.

As an example, the first magnetic coupling factor can be equal to the second magnetic coupling factor. As another example, the first magnetic coupling factor can be different than the second magnetic coupling factor. The use of tunable magnetic coupling circuit 72, in combination with differential tunable capacitor 70, within the phase noise tail filter can be technically advantageous by providing a wider (extended) tuning range without sacrificing the overall Q factor of the filter (e.g., by allowing for the switches within tuning component 70 to be large), thus overcoming the tradeoff between filter tuning range and quality factor that would otherwise be present if tunable magnetic coupling circuit 72 were to be omitted.

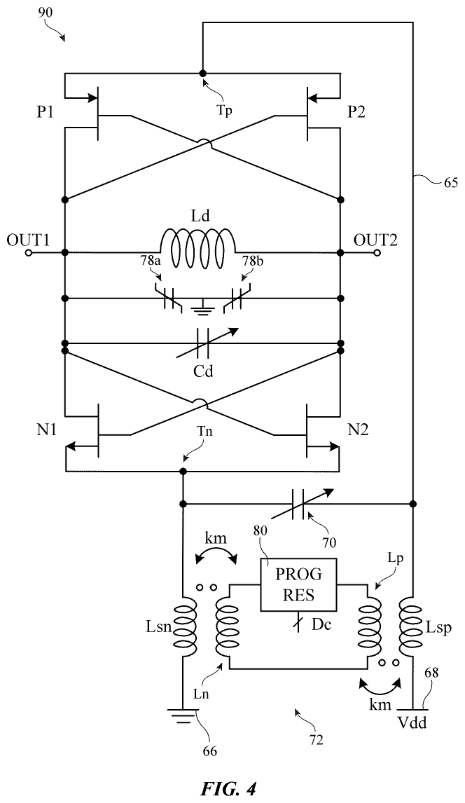

FIG. 4 is a circuit diagram showing an illustrative implementation of complementary oscillator circuitry 90 of the type described in connection with FIG. 3. As shown in FIG. 4, oscillator circuitry 90 can include n-type transistors N1 and N2, p-type transistors P1 and P2, capacitors 78a and 78b, an output capacitor such as tunable load capacitor Cd, an output inductor such as load inductor Ld, and one or more associated coils such as tail coils Lsn and Lsp.

Transistors N1 and N2 may be n-type (n-channel) transistors such as n-type metal-oxide-semiconductor (NMOS) devices and can represent the n-type switches 62 shown in FIG. 3. Transistor N1 may have a source terminal coupled to a first tail node such as tail node Tn, a drain terminal coupled to a first output terminal OUT1 of circuitry 90, and a gate terminal that is cross-coupled to a second output terminal OUT2 of circuitry 90. Transistor N2 may have a source terminal coupled to the first tail node Tn, a drain terminal coupled to the second output terminal OUT2, and a gate terminal that is cross-coupled to the first output terminal OUT1.

Output terminals OUT1 and OUT2 may serve collectively as a differential output port of oscillator circuitry 90. Oscillating (local oscillator or “LO”) signals can be generated on the differential output port. Transistors N1 and N2 arranged in this way are sometimes referred to as “cross-coupled”differential n-type transistors.

The terms “source” and “drain” terminals used to refer to current-conveying terminals of a transistor may be used interchangeably and are sometimes referred to as “source-drain” terminals. Thus, the source terminal of transistor N1 can sometimes be referred to as a first source-drain terminal, and the drain terminal of transistor N1 can be referred to as a second source-drain terminal (or vice versa). The term “activate” with respect to a switch (or transistor) may refer to or be defined herein as an action that places the switch in an “on” or low-impedance state such that the two terminals of the switch are electrically connected to conduct current. The term “deactivate” with respect to a switch (or transistor) may refer to or be defined herein as an action that places the switch in an “off” or high-impedance state such that the two terminals of the switch/transistor are electrically disconnected with minimal leakage current.

At the other end, transistors P1 and P2 may be p-type (p-channel) transistors such as p-type metal-oxide-semiconductor (PMOS) devices and can represent the p-type switches 64 shown in FIG. 3. Transistor P1 may have a source terminal coupled to a second tail node such as tail node Tp, a drain terminal coupled to the first output terminal OUT1 of circuitry 90, and a gate terminal that is cross-coupled to the second output terminal OUT2 of circuitry 90.

Transistor P2 may have a source terminal coupled to the second tail node Tp, a drain terminal coupled to the second output terminal OUT2, and a gate terminal that is cross-coupled to the first output terminal OUT1. Transistors P1 and P2 arranged in this way are sometimes referred to as “cross-coupled”differential p-type transistors.

A first capacitor 78a may have a first terminal coupled to output terminal OUT1 and a second terminal coupled to the ground line. A second capacitor 78b may have a first terminal coupled to output terminal OUT2 and a second terminal coupled to ground. Load (output) inductor Ld may have a first terminal coupled to output terminal OUT1 and a second terminal coupled to output terminal OUT2 (e.g., load inductor Ld may be coupled across the differential output port of oscillator circuitry 90). Tunable load (output) capacitor Cd may have a first terminal coupled to output terminal OUT1 and a second terminal coupled to output terminal OUT2. Load inductor Ld may thus be coupled in parallel with load capacitor Cd. Capacitor Cd may be implemented as a programmable bank of capacitors or other types of adjustable capacitive structure.

The first tail coil Lsn may have a first terminal coupled to tail node Tn and a second terminal coupled to ground power supply line 66. The second tail coil Lsp may have a first terminal coupled to tail node Tp and a second terminal coupled to positive power supply line 68. Tunable capacitor 70 can have a first terminal coupled to tail node Tn and a second terminal coupled to tail node Tp (e.g., capacitor 70 can be differentially coupled across the two tail nodes).

As shown in FIG. 4, tunable magnetic coupling circuit 72 can include one or more coils such as a first coupling coil Ln and a second coupling coil Lp and can further include a programmable resistor such as programmable resistor 80. The first coupling coil Ln, sometimes referred to as a first tuning coil, can be magnetically coupled to tail coil Lsn by a first coupling coefficient km. The second coupling coil Lp, sometimes referred to as a second tuning coil, can be magnetically coupled to tail coil Lsp by a second coupling coefficient km. The first and second coupling coefficients can be equal or can be different. Coils Lsn and Ln being magnetically coupled to each other can form a first transformer (e.g., a first balun). Similarly, coils Lsp and Lp being magnetically coupled to each other can form a second transformer (e.g., a second balun). A “balun” can refer to herein as a particular type of transformer where one of its coils has one terminal coupled to a static voltage line. For instance, the first balun has coil Lsn with one terminal coupled to the Vss ground line 66, whereas the second balun has coil Lsp with one terminal coupled to the Vdd power supply line 68. Such type of phase noise tail filter is thus sometimes referred to as a “transformer/balun based” phase noise filter. All of the components within the transformer based phase noise filter, including components 70, Lsn, Ln, Lsp, Lp, and 80, can form a resonant circuit (tank) having a resonant frequency.

Programmable resistor 80 can be coupled between the first and second tuning coils Ln and Lp. In particular, first tuning coil Ln can have a first terminal coupled to programmable resistor 80 and a second terminal coupled to second tuning coil Lp. At the other end, second tuning coil Lp can have a first terminal coupled to programmable resistor 80 and a second terminal coupled to first tuning coil Ln. In other words, components Ln, Lp, and 80 can be coupled in a loop. Programmable resistor 80 can be configured to receive a digital control signal Dc for tuning a resistance of resistor 80. Programmable resistor 80 can be configured, based on digital control signal Dc, to provide a plurality of resistance values, 2-10 different resistance values, 10-100 different resistance values, 100-1000 different resistance values, or more than 1000 different resistance values.

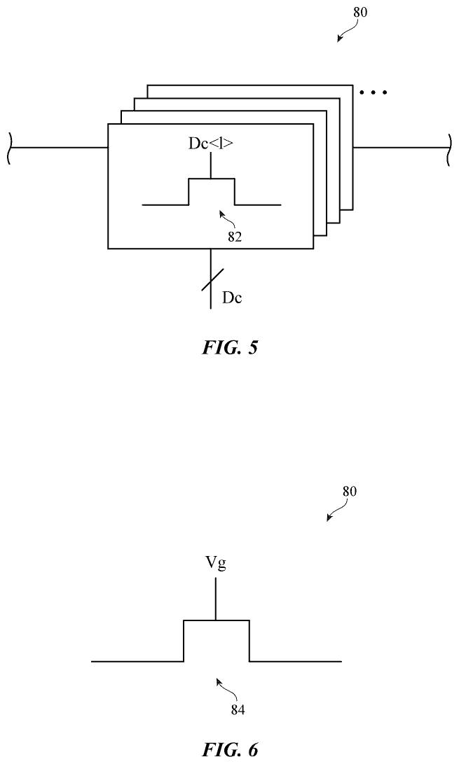

Programmable resistor 80 can be implemented in various ways. FIG. 5 is a circuit diagram of an illustrative programmable resistor 80. As shown in FIG. 5, programmable resistor 80 can include an array or bank of switches 82. The bank of switches can be controlled by digital control signal Dc. Digital control signal Dc can be configured to selectively activate one or more switches 82 within programmable resistor 80. For example, a first switch 82 in the bank of switches can be controlled by a first digital bit Dc<1>, a second switch 82 in the bank of switches can be controlled by a second digital bit Dc<2>, and so on. The opposing (source-drain) terminals of each switch 82 can be coupled to the first and second tuning coils Ln and Lp, respectively.

All of the switches 82 can be deactivated (e.g., by setting all of the digital control bits to logic “0”) such that programmable resistor 80 is configured to provide a maximum (high) resistance value. Conversely, all of the switches 82 can be activated (e.g., by setting all of the digital control bits to logic “1”) such that programmable resistor 80 is configured to provide a minimum (low) resistance value. If desired, a quarter of the switches 82 can be selectively activated to provide a first intermediate resistance value greater than the low resistance value. If desired, half of the switches 82 can be selectively activated to provide a second intermediate resistance value greater than the first intermediate resistance value. In general, any portion (subset) of the switches 82 can be selectively switched into use to provide an intermediate resistance value between the low (minimum) and high (maximum) resistance values.

The example of FIG. 5 in which programmable resistor 80 is implemented as a bank of digitally controlled switches is illustrative. FIG. 6 shows another example where programmable resistor 80 is implemented as a single transistor 84. As shown in FIG. 6, transistor 84 can have a gate terminal configured to receive an analog gate voltage Vg. The opposing (source-drain) terminals of transistor 84 can be coupled to the first and second tuning coils Ln and Lp, respectively. Gate voltage Vg can be set to a low voltage (e.g., Vss) such that programmable resistor 80 is configured to provide a maximum (high) resistance value.

Conversely, gate voltage Vg can be set to a high voltage (e.g., Vdd) such that programable resistor 80 is configured to provide a minimum (low) resistance value. If desired, gate voltage Vg can be set to some intermediate voltage level between Vss and Vdd such that programmable resistor 80 is configured to provide an intermediate resistance value between the low (minimum) and high (maximum) resistance values. The examples of FIGS. 5 and 6 are illustrative. If desired, other ways of implementing a programmable or variable resistor 80 can be employed. Resistor 80 can sometimes be referred to as an adjustable or tunable resistive circuit.

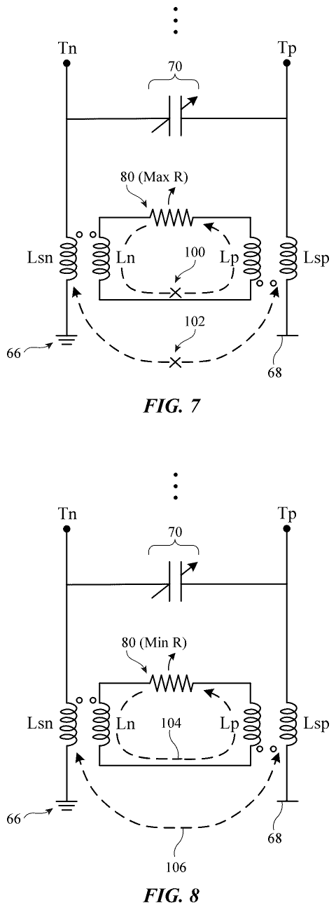

Tunable magnetic coupling circuit 72 can be operable in a plurality of coupling modes based on the resistance of programmable resistor 80. FIG. 7 is circuit diagram of the phase noise tail filter configured to operate in a first coupling mode. In the first coupling mode, programmable resistor 80 may be configured to provide a maximum (high) resistance value. If programmable resistor 80 were implemented as a bank of digitally controlled switches as shown in the example of FIG. 5, then all or almost all of the switches 82 can be deactivated. If programmable resistor 80 were implemented as an analog controlled transistor 84 as shown in the example of FIG. 6, then the gate voltage Vg can be set to a low voltage (e.g., ground voltage Vss or a negative voltage). Configured in this way, no current can flow between coils Ln and Lp due to the high resistance of resistor 80, as denoted by marking 100. When no current is flowing between coils Ln and Lp, tail coil Lsn is magnetically decoupled from tail coil Lsp, as denoted by marking 102 (e.g., tail coils Lsn and Ls are not magnetically coupled to each other). As a result, the effective inductance of the phase noise filter will be equal to the individual Lsn and Lsp inductances and can be relatively high. This corresponds to a high inductance mode, which might be suitable for a low resonant frequency operation.

FIG. 8 is circuit diagram of the phase noise tail filter configured to operate in a second coupling mode. In the second coupling mode, programmable resistor 80 may be configured to provide a minimum (low) resistance value. If programmable resistor 80 were implemented as a bank of digitally controlled switches as shown in the example of FIG. 5, then all or almost all of the switches 82 can be activated. If programmable resistor 80 were implemented as an analog controlled transistor 84 as shown in the example of FIG. 6, then the gate voltage Vg can be set to a high voltage (e.g., positive power supply voltage Vdd).

Configured in this way, current can flow through the loop between coils Ln and Lp due to the low resistance of resistor 80, as denoted by current flow 104. When current is flowing between coils Ln and Lp, tail coil Lsn can be magnetically coupled to tail coil Lsp, as denoted by magnetic coupling path 106 (e.g., tail coils Lsn and Ls are magnetically coupled to each other). As a result, the effective inductance of the phase noise filter will be lower than the individual Lsn and Lsp inductances. This corresponds to a low inductance mode, which might be suitable for a high resonant frequency operation.

FIGS. 7 and 8 illustrate two opposite extremes where programmable resistor 80 is set to a maximum value (FIG. 7) or a minimum value (FIG. 8). In general, programmable resistor 80 can be set to one or more intermediate resistance values to support a wide range of intermediate resonant frequencies. In other words, the programmability of resistor 80 can provide an extended tuning range across a wide range of operating frequencies for the phase noise tail filter without sacrificing the overall quality factor.

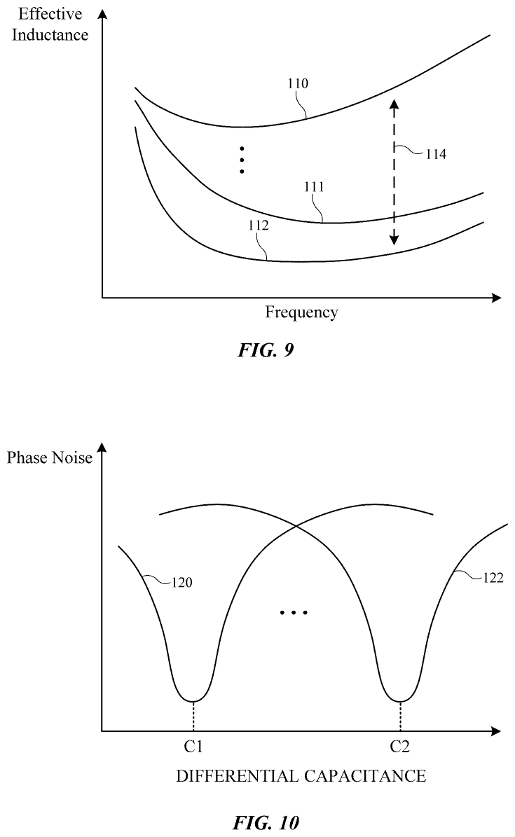

FIG. 9 is a plot of effective inductance of the phase noise filter as a function of frequency across different programmable resistor values. Curve 110 may represent the effective inductance profile of the filter when programmable resistor 80 is set to a maximum resistance.

Curve 112 may represent the effective inductance profile of the filter when programmable resistor 80 is set to a minimum resistance. Curve 111 may represent the effective inductance profile of the filter when programmable resistor 80 is set close to the minimum resistance. As shown by FIG. 9, adjusting the resistance of resistor 80 can provide a broad range 114 of effective filter inductance for supporting different resonance frequencies.

FIG. 10 is a plot of phase noise as a function of the differential capacitance (e.g., the capacitance of tunable capacitor 70) across different programmable resistor values. Curve 120 may represent the phase noise profile at a specific offset from the carrier frequency of the oscillator circuitry when programmable resistor 80 is set to a maximum resistance. In such configuration, the capacitance of component 70 can be set to a first capacitance value C1 to provide optimal phase noise rejection. Curve 122 may represent the phase noise profile at a specific offset from the carrier frequency of the oscillator circuitry when programmable resistor 80 is set to a minimum resistance. In such configuration, the capacitance of component 70 can be set to a second capacitance value C2, greater than C1, to provide optimal phase noise rejection. As shown by FIG. 10, the capacitance of component 70 might be adjusted depending on the resistance of programmable resistor 80 to optimize for phase noise rejection.

The methods and operations described above in connection with FIGS. 1-10 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Oscillator circuitry comprising:
a pair of n-type transistors coupled to a first tail node;
a pair of p-type transistors coupled to a second tail node;
output terminals coupled between the pair of n-type transistors and the pair of p-type transistors, the output terminals configured to provide an oscillating signal;
a first tail coil coupled to the first tail node; and
a tunable magnetic coupling circuit magnetically coupled to the first tail coil.

2. The oscillator circuitry of claim 1, further comprising:
a load inductor coupled across the output terminals; and
a load capacitor coupled across the output terminals.

3. The oscillator circuitry of claim 1, further comprising:
a second tail coil coupled to the second tail node and magnetically coupled to the tunable magnetic coupling circuit.

4. The oscillator circuitry of claim 3, further comprising:
a tunable capacitor having a first terminal coupled to the first tail node and having a second terminal coupled to the second tail node.

5. The oscillator circuitry of claim 3, wherein the tunable magnetic coupling circuit comprises:
a first tuning coil magnetically coupled to the first tail coil;
a second tuning coil magnetically coupled to the second tail coil; and
a programmable resistor coupled to the first and second tuning coils in a loop.

6. The oscillator circuitry of claim 3, wherein:
the tunable magnetic coupling circuit comprises a programmable resistor;
the first tail coil is magnetically decoupled from the second tail coil when the programmable resistor is configured to provide a first resistance value; and
the first tail coil is magnetically coupled to the second tail coil when the programmable resistor is configured to provide a second resistance value different than the first resistance value.

7. The oscillator circuitry of claim 3, wherein:
the tunable magnetic coupling circuit comprises a programmable resistor;
the first tail coil is magnetically decoupled from the second tail coil when the programmable resistor is configured to provide a first resistance value; and
the first tail coil is magnetically coupled to the second tail coil when the programmable resistor is configured to provide a second resistance value less than the first resistance value.

8. The oscillator circuitry of claim 3, wherein the tunable magnetic coupling circuit comprises a programmable resistor having a plurality of switches controlled by a digital signal.

9. The oscillator circuitry of claim 3, wherein the tunable magnetic coupling circuit comprises a programmable resistor having a transistor controlled by an analog gate voltage.

10. The oscillator circuitry of claim 1, further comprising:
a second tail coil coupled to the second tail node and magnetically coupled to the tunable magnetic coupling circuit; and
a tunable capacitor having a first terminal coupled to the first tail node and having a second terminal coupled to the second tail node, wherein:
the tunable capacitor is configured to provide a first capacitance value for optimizing phase noise rejection for the oscillator circuitry when a programmable resistor in the tunable magnetic coupling circuit has a first resistance value; and
the tunable capacitor is configured to provide a second capacitance value, different than the first capacitance value, for optimizing phase noise rejection for the oscillator circuitry when the programmable resistor has a second resistance value different than the first resistance value.

11. Circuitry comprising:
a pair of n-type transistors coupled to a first tail node;
a pair of p-type transistors coupled to a second tail node;
a first tail coil coupled to the first tail node;
a second tail coil coupled to the second tail node; and
a tunable magnetic coupling circuit operable in a first coupling mode for providing a first amount of magnetic coupling between the first and second tail coils and further operable in a second coupling mode for providing a second amount of magnetic coupling, different than the first amount of magnetic coupling, between the first and second tail coils.

12. The circuitry of claim 11, further comprising:
an adjustable capacitor having a first node coupled to the first tail node and having a second node coupled to the second tail node.

13. The circuitry of claim 11, wherein the tunable magnetic coupling circuit comprises:
a first tuning coil magnetically coupled to the first tail coil;
a second tuning coil magnetically coupled to the second tail coil; and
a programmable resistor having a first terminal coupled to the first tuning coil and having a second terminal coupled to the second tuning coil.

14. The circuitry of claim 13, wherein the programmable resistor is configured to provide a first resistance value when the tunable magnetic coupling circuit is operated in the first coupling mode and is configured to provide a second resistance value, different than the first resistance value, when the tunable magnetic coupling circuit is operated in the second coupling mode.

15. The circuitry of claim 13, wherein:
when the tunable magnetic coupling circuit is configured in the first coupling mode, the first tail coil is magnetically decoupled from the second tail coil; and
when the tunable magnetic coupling circuit is configured in the second coupling mode, the first tail coil is magnetically coupled to the second tail coil.

16. The circuitry of claim 15, wherein:
when the tunable magnetic coupling circuit is configured in the first coupling mode, the circuitry is configured to operate at a first resonant frequency; and
when the tunable magnetic coupling circuit is configured in the second coupling mode, the circuitry is configured to operate at a second resonant frequency higher than the first resonant frequency.

17. Circuitry comprising:
a pair of cross-coupled n-type transistors coupled to a first tail node;
a pair of cross-coupled p-type transistors coupled to a second tail node;
a load inductor coupled between the pair of cross-coupled n-type transistors and the pair of cross-coupled p-type transistors;
a load capacitor coupled in parallel with the load inductor; and
a phase noise filter coupled between the first and second tail nodes and having a programmable resistor configured to provide:
a first resistance in a first mode, wherein the phase noise filter exhibits a first inductance in the first mode; and
a second resistance, less than the first resistance, in a second mode, wherein the phase noise filter exhibits a second inductance, less than the first inductance, in the second mode.

18. The circuitry of claim 17, wherein the phase noise filter further comprises:
a first tuning coil and a second tuning coil coupled to the programmable resistor in a loop.

19. The circuitry of claim 18, wherein the phase noise filter further comprises:
a first tail coil coupled to the first tail node and magnetically coupled to the first tuning coil; and
a second tail coil coupled to the second tail node and magnetically coupled to the second tuning coil.

20. The circuitry of claim 17, wherein the phase noise filter further comprising:
a first transformer or balun coupled to a first terminal of the programmable resistor; and
a second transformer or balun coupled to a second terminal of the programmable resistor.
